(19) United States
(12) Patent Application Publication
(10) Pub. No.: US 2025/0204216 A1
(43) Pub. Date: Jun. 19, 2025

(54) DISPLAY DEVICE

(71) Applicant: LG Display Co., Ltd., Seoul (KR)

(72) Inventor: JaeYoung OH, Goyang-si (KR)

(73) Assignee: LG Display Co., Ltd., Seoul (KR)

(21) Appl. No.: 18/774,317

(22) Filed: Jul. 16, 2024

(30) Foreign Application Priority Data
Dec. 19, 2023 (KR) 10-2023-0186165

(51) Int. Cl. H10K 59/80; H10K 59/124

(52) U.S. Cl. CPC H10K 59/873; H10K 59/124

(57) ABSTRACT

A display device may include a substrate; an active area; a non-active area in the active area; a first interlayer insulation layer disposed on the substrate; a second interlayer insulation layer disposed on the first interlayer insulation layer; at least one planarization layer disposed on the second interlayer insulation layer; and an encapsulation layer disposed on the planarization layer. The non-active area may include a through hole and a surrounding area surrounding the through hole. At least a part of the second interlayer insulation layer and at least a part of the planarization layer disposed in the surrounding area may have a convex and concave structure. At least a part of the encapsulation layer may be disposed in the surrounding area adjacent to the through hole in such a way that a thickness thereof may decrease toward the through hole.

### CROSS-REFERENCE TO RELATED APPLICATIONS

This application claims the benefit of and priority to Korean Patent Application No. 10-2023-0186165 filed on Dec. 19, 2023, the entirety of which is incorporated herein by reference for all purposes.

### BACKGROUND

### 1. Technical Field

The present disclosure relates to a display device, and more particularly to, for example, a display device preventing interfacial separation in an area adjacent to a through hole and securing excellent reliability.

### 2. Description of the Related Art

Display devices may be used for various types of devices such as a TV, a monitor, a tablet computer, a navigator, a game console, a mobile phone and the like. A variety of display devices such as a liquid crystal display device (LCD), an organic light emitting display device (OLED) and the like may be used as a display device.

There is a growing demand for a reduced bezel area that is an outer part of a display device, and accordingly, research on technologies for accommodating components such as a camera or a variety of sensors in an active area has been conducted actively.

The description of the related art should not be assumed to be prior art merely because it is mentioned in or associated with this section. The description of the related art includes information that describes one or more aspects of the subject technology, and the description in this section does not limit the invention.

### SUMMARY

To accommodate components such as a camera and the like in an active area, a display device may have a through hole, where a partial area of a substrate and components on the substrate are removed. The though hole is vulnerable to infiltration of moisture. The infiltration of moisture through the through hole facilitates the degradation of a component such as a camera accommodated in the through hole and an organic light emitting diode disposed in the active area. Additionally, an interface showing weak adhesion is likely to separate due to the infiltration of moisture. Further, a functional layer such as a polarization layer may be disposed on an encapsulation layer, and at this time, due to the shrinkage of such a functional layer, stress applied to an organic layer and an inorganic layer disposed under the functional layer causes the separation of an interface between the organic layer and the inorganic layer.

To solve the problems and needs of the related art, including the foregoing problem, in one or more aspects, an objective of the present disclosure is to provide a display device capable of minimizing the infiltration of moisture through a through hole, preventing an interfacial separation between an organic layer and an inorganic layer and securing excellent reliability.

Objects of the present disclosure are not limited to the above-mentioned objects, and other objects, which are not mentioned above, can be clearly understood by those skilled in the art from the following descriptions.

A display device of one or more example embodiments comprises a substrate, an active area, a non-active area in the active area, a first interlayer insulation layer disposed on the substrate, a second interlayer insulation layer disposed on the first interlayer insulation layer, at least one planarization layer disposed on the second interlayer insulation layer, and an encapsulation layer disposed on the at least one planarization layer, wherein the non-active area comprises a through hole and a surrounding area surrounding the through hole, at least a part of the second interlayer insulation layer and at least a part of the at least one planarization layer disposed in the surrounding area have a convex and concave structure, at least a part of the encapsulation layer is disposed in the surrounding area adjacent to the through hole, and a thickness of the at least a part of the encapsulation layer decreases toward the through hole.

A display device of one or more example embodiments comprises a substrate, an active area comprising a plurality of sub pixels for displaying an image, a non-active area in the active area, an interlayer insulation layer disposed on the substrate, a planarization layer disposed on the interlayer insulation layer, and an encapsulation layer disposed on the planarization layer, wherein the non-active area comprises a through hole and a surrounding area surrounding the through hole, a convex and concave structure is comprised in at least one or each of the following: the interlayer insulation layer disposed in the surrounding area and the planarization layer disposed in the surrounding area, and compared to an upper surface of the encapsulation layer disposed in the surrounding area away from the through hole, the upper surface of the encapsulation layer disposed in the surrounding area adjacent to the through hole is closer to the substrate.

A display device of one or more example embodiments comprises a substrate, an active area comprising a plurality of sub pixels for displaying an image, a non-active area in the active area, a planarization layer disposed on the substrate, and an encapsulation layer disposed on the planarization layer, wherein the non-active area comprises a through hole and a surrounding area surrounding the through hole, the planarization layer disposed in the surrounding area comprises a convex and concave structure, and compared to an upper surface of the encapsulation layer disposed in the surrounding area away from the through hole, the upper surface of the encapsulation layer disposed in the surrounding area adjacent to the through hole is closer to the substrate.

Accordingly, in the area adjacent to the through hole, the separation of an interfacial film, caused by adhesive failure generated between the second interlayer insulation layer and the planarization layer, may be solved, making it possible to embody a display device having excellent reliability.

Other detailed matters of example embodiments are included in the detailed description and the drawings.

In the display device of one or more example embodiments of the present disclosure, at least a part of each of the second interlayer insulation layer and the planarization layer disposed in the area adjacent to the through hole has a convex and concave structure, making it possible to delay the infiltration of moisture.

In the display device of one or more example embodiments of the present disclosure, interfacial separation between the second interlayer insulation layer and the planarization layer, caused by the infiltration of moisture, may be prevented, making it possible to ensure excellent reliability.

In the display device of one or more example embodiments of the present disclosure, the encapsulation layer disposed in the surrounding area is provided in such a way that a thickness thereof decreases toward the through hole. Accordingly, stress caused by the shrinkage of functional layers and the like and applied to layers disposed under the functional layers may decrease. Thus, deterioration in adhesion between the second interlayer insulation layer and the planarization layer adjacent to the through hole may be minimized, making it possible to provide a display device having excellent reliability.

The effects according to the present disclosure are not limited to the foregoing, and other various effects are described in the present disclosure.

Other apparatuses, devices, methods, features and advantages will be, or will become, apparent to one with skill in the art upon examination of the drawings and detailed description herein. It is intended that all such apparatuses, devices, methods, features and advantages be included within this description, be within the scope of the present disclosure, and be protected by the following claims. Nothing in this section should be taken as a limitation on the claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure. In the drawings:

FIG. 1 is a plan view of a display device of an example embodiment;

FIG. 2 is an example of an enlarged view of area X in FIG. 1;

FIG. 3 is an example of a cross-sectional view along I-I′ in FIG. 1;

FIG. 4 is an example of a cross-sectional view along II-II′ in FIG. 2;

FIGS. 5A to 5C are cross-sectional views for describing a manufacturing method of a non-active area in the display device of an example embodiment;

FIG. 6 is a cross-sectional view of a first non-active area in a display device of another example embodiment;

FIGS. 7A and 7B are cross-sectional views for describing a manufacturing method of a non-active area in the display device of another example embodiment; and

FIG. 8 is a cross-sectional view of a first non-active area in a display device of yet another example embodiment.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, regions, components, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, regions, components, sections, members, parts, regions, areas, portions, and/or the like) are described using any of the terms such as “on,” “on a top of,” “upon,” “on top of,” “over,” “under,” “above,” “upper,” “below,” “lower,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “subsequent,” “next,” “before,” “preceding,” “prior to,” or the like, a case that is not consecutive or not sequential may be included and thus one or more other events may occur therebetween, unless a more limiting term, such as “just,” “immediate (ly),” or “direct (ly),” is used.

It is understood that, although the terms “first,” “second,” and the like may be used herein to describe various elements (e.g., layers, films, regions, components, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, region, component, section, member, part, region, area, portion, or the like) is “connected,” “coupled,” “attached,” “adhered,” “linked,” or the like to another element, the element can not only be directly connected, coupled, attached, adhered, linked, or the like to another element, but also be indirectly connected, coupled, attached, adhered, linked, or the like to another element with one or more intervening elements disposed or interposed between the elements, unless otherwise specified.

For the expression that an element (e.g., layer, film, region, component, section, member, part, region, area, portion, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phrase that an element (e.g., layer, film, region, component, section, member, part, region, area, portion, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element. The phrase “through” may be understood, for example, to be at least partially through or entirely through. The phrase that an element (e.g., layer, film, region, component, section, member, part, region, area, portion, or the like) “contacts,” “overlaps,” or the like with another element may be understood, for example, as that at least a portion of the element contacts, overlaps, or the like with a least a portion of another element.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “some,” “some elements,” “a portion,” “portions,” “at least a portion,” “at least portions,” “a part,” “at least a part,” “parts,” “at least parts,” “one or more,” or the like of the plurality of elements can represent (i) one element of the plurality of elements, (ii) a part of the plurality of elements, (iii) parts of the plurality of elements, (iv) multiple elements of the plurality of elements, or (v) all of the plurality of elements. Moreover, at least a portion (or a part) of an element can represent (i) a portion (or a part) of the element, (ii) one or more portions (or parts) of the element, or (iii) the element, or the entirety of the element. A phrase that a plurality of first elements are connected to a plurality of second elements may describe, for example, that at least a part (or one or more first elements) of a plurality of first elements are connected to at least a part (or one or more second elements) of a plurality of second elements.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, section, member, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

Hereinafter, display devices, features and methods according to example embodiments of the present disclosure will be described in detail with reference to accompanying drawings.

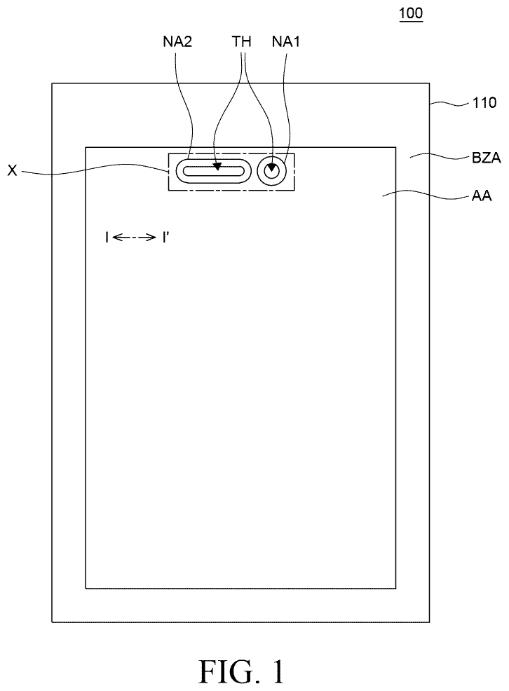

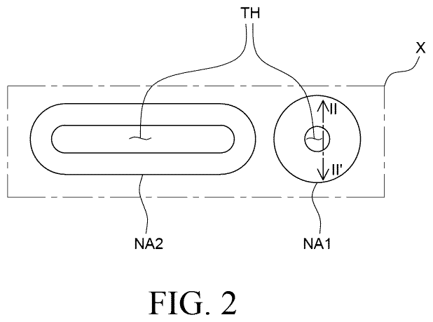

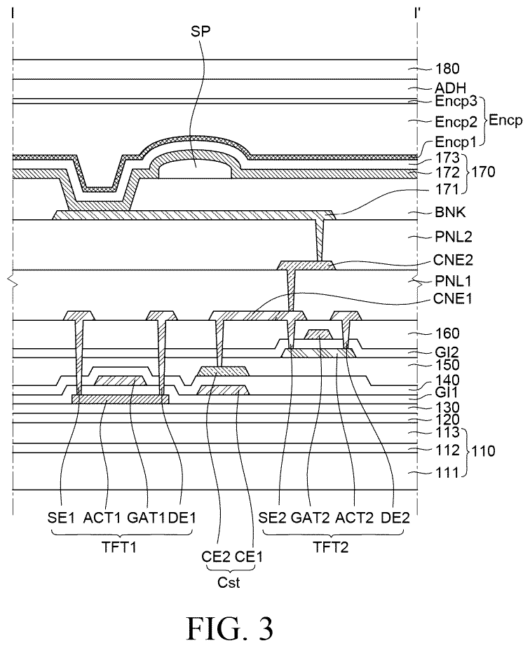

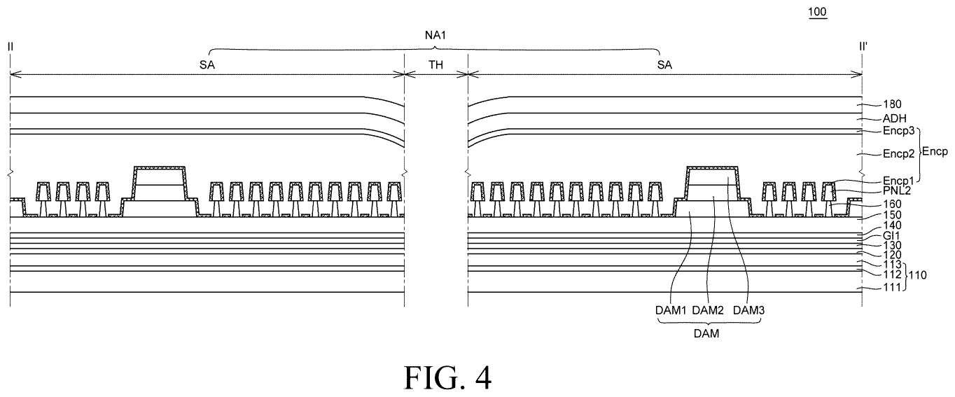

FIG. 1 is a plan view of a display device of an example embodiment. FIG. 2 is an example of an enlarged view of area X in FIG. 1. FIG. 3 is an example of a cross-sectional view along I-I′ in FIG. 1. FIG. 4 is an example of a cross-sectional view along II-II′ in FIG. 2.

Referring to FIGS. 1 to 4, a display device 100 according to an example embodiment of the present disclosure comprises a substrate 110, a substrate buffer layer 120, an active buffer layer 130, a first thin film transistor TFT1, a first interlayer insulation layer 140, an intermediate buffer layer 150, a storage capacitor Cst, a second thin film transistor TFT2, a second interlayer insulation layer 160, a first planarization layer PLN1, a second planarization layer PLN2, an organic light emitting diode 170, an encapsulation layer Encp, an adhesive layer ADH, and an optical film 180.

The substrate 110 supports other components of the display device 100. The substrate 110 may be comprised of an insulation material. For example, the substrate 110 may be a glass substrate or a polymer substrate. For example, the substrate 110 may be a polyimide (PI) substrate, but not be limited thereto. The substrate 110 may have a multi-layered structure. For example, the substrate 110 may have a multi-layered structure in which a first polyimide layer 111 and a second polyimide layer 113 are stacked. At this time, the substrate may have excellent stiffness and support the components formed on the substrate 110, without being deformed in the process where the displace device 100 is manufactured. In the case where the substrate 110 is a polymer substrate, the substrate 110 may further comprise a barrier layer 112 to ensure barrier properties. The barrier layer 112 may be disposed between the first polyimide layer 111 and the second polyimide layer 113, and improve barrier properties. For example, the barrier layer 112 may be comprised of an inorganic insulation material such as a silicon oxide (SiOx) or a silicon nitride (SiNx).

The display device 100 (or the substrate 110) comprises areas defined as an active area AA and a bezel area BZA. The active area AA is an area that displays an image. In the active area AA, a plurality of sub pixels for displaying an image and a driving circuit for driving a plurality of sub pixels may be disposed. In each of the plurality of sub pixels as an individual unit emitting light, an organic light emitting diode 170 may be disposed. The plurality of sub pixels may comprise a red sub pixel, a green sub pixel, a blue sub pixel and a white sub pixel, but not be limited thereto. The driving circuit may comprise a variety of transistors, a storage capacitor and lines and the like that are used to drive the plurality of sub pixels. For example, the driving circuit may be comprised of various types of components such as a driving transistor, a switching transistor, a sensing transistor, a storage capacitor, a gate line, a data line and the like, but not limited thereto.

The bezel area BZA is disposed to surround the active area AA and is an area where an image is not displayed. In the bezel area BZA, various types of lines, various types of driving ICs and the like for driving sub pixels disposed in the active area AA are disposed. For example, in the bezel area BZA, various types of driving ICs such as a gate driver IC, a data driver IC, and the like may be disposed, but not limited thereto.

The display device 100 (or the substrate 110) comprises a first non-active area NA1 and a second non-active area NA2 in the active area AA. In the drawings, two non-active areas are included in the active area AA, but not limited thereto. The first non-active area NA1 and the second non-active area NA2 may be an area where light emitting diodes 170 are not disposed. Each of the first non-active area NA1 and the second non-active area NA2 comprises a through hole TH. The through hole TH may be a hole that passes through the substrate 110, the substrate buffer layer 120, the active buffer layer 130, the first interlayer insulation layer 140, the intermediate buffer layer 150, the second interlayer insulation layer 160, the second planarization layer PLN2, the encapsulation layer Encp, the adhesive layer ADH and the optical film 180. The through hole TH may be formed to correspond to a camera or a sensor. For example, a camera is accommodated in the through hole TH of the first non-active area NA1, and a sensor module such as an optical sensor may be accommodated in the through hole TH of the second non-active area NA2, but not limited thereto.

On the substrate 110, the substrate buffer layer 120 for protecting the thin film transistor TFT1, TFT2 and the organic light emitting diode 170 from moisture, external air, foreign substances and the like infiltrating from the outside, and for preventing damage to the substrate 110 during manufacturing of the display device 100 may be disposed. The substrate buffer layer 120 is disposed on the front surface of substrate 110, corresponding to the active area AA, the non-active area NA1, NA2 and the bezel area BZA. The substrate buffer layer 120 may be formed of an inorganic insulation material. For example, the substrate buffer layer 120 may be formed of a material selected from a silicon oxide layer, a silicon nitride layer, and a silicon oxynitride layer, but not limited thereto. The substrate buffer layer 120 may have a single-layered structure or a multi-layered structure. For example, the substrate buffer layer 120 may have a multi-layered structure in which a silicon oxide layer and a silicon nitride layer are stacked, but not be limited thereto.

Though not illustrated in the drawing, on the substrate buffer layer 120, a light shielding layer for protecting the first active layer ACT1 of the first thin film transistor TFT1 from external light such as ultraviolet rays may be disposed. For example, the light shielding layer may be formed of one or more metals, such as molybdenum (Mo), titanium (Ti), aluminum (Al), the like, and/or an alloy thereof, but not limited thereto. In one example, the light shielding layer may be disposed to overlap the first active layer ACT1, and in another example, the light shielding layer may be disposed to overlap all the first active layer ACT1, the storage capacitor Cst and a second active layer ACT2.

On the substrate buffer layer 120, the active buffer layer 130 is disposed. The active buffer layer 130 may prevent hydrogen or foreign substances and the like from spreading to the substrate 110 in the process where the thin film transistor is formed, and prevent moisture from infiltrating the thin film transistor from the outside. The active buffer layer 130 is disposed on the front surface of the substrate 110, corresponding to the active area AA, the non-active area NA1, NA2 and the bezel area BZA. For example, the active buffer layer 130 may be formed of a material selected from a silicon oxide layer, a silicon nitride layer and a silicon oxynitride layer, but not limited thereto. The active buffer layer 130 may have a single-layered structure and a multi-layered structure.

Hereinafter, each of the first thin film transistor TFT1, the storage capacitor Cst, the second thin film transistor TFT2 and the organic light emitting diode 170 that are disposed in the active area AA is specifically described with reference to FIG. 3.

In the active area AA, the first thin film transistor TFT1, the storage capacitor Cst, the second thin film transistor TFT2 and the organic light emitting diode 170 are disposed on the active buffer layer 130. The first thin film transistor TFT1 comprises a first active layer ACT1, a first gate electrode GAT1, a first source electrode SE1 and a first drain electrode DE1. The first thin film transistor TFT1 may be an LTPS thin film transistor, but not limited thereto. The storage capacitor Cst comprises a first capacitor electrode CE1 and a second capacitor electrode CE2. The second thin film transistor TFT2 comprises a second active layer ACT2, a second gate electrode GAT2, a second source electrode SE2 and a second drain electrode DE2. The second thin film transistor TFT2 may be an oxide semiconductor thin film transistor, but not limited thereto.

The first active layer ACT1 may be disposed on the active buffer layer 130. The first active layer ACT1 may comprise poly silicon formed of an amorphous silicon (a-Si) material. For example, the first active layer ACT1 is formed in such a way that an amorphous silicon (a-Si) material is deposited on the active buffer layer 130, and poly silicon is formed by proceeding with dehydrogenation and crystallization and then patterned. Then the first active layer ACT1 may be formed via activation and hydrogenation, but not limited thereto.

A first gate insulation layer GI1 is disposed on the first active layer ACT1. The first gate insulation layer GI1 may be disposed across the active area AA and the non-active area NA1, NA2. For example, the first gate insulation layer GI1 may be formed of a material selected from a silicon oxide layer, a silicon nitride layer and a silicon oxynitride layer, but not limited thereto. The first gate insulation layer GI1 may have a single-layered structure or a multi-layered structure. In the case where the first gate insulation layer GI1 has a multi-layered structure, a silicon nitride layer with relatively high hydrogen content is preferably disposed under a silicon oxide layer, and the silicon oxide layer with relatively low hydrogen content is preferably disposed on the silicon nitride layer, to minimize the spread of hydrogen generated during processing to the second active layer ACT2 of the second thin film transistor TFT2. In the case where the spread of hydrogen is minimized, the second active layer ACT2 is prevented from becoming conductive, such that a change in the threshold voltage of the second thin film transistor TFT2 is minimized.

The first gate insulation layer GI1 is provided with a contact hole for connecting the first source electrode and the first drain electrode of the first thin film transistor TFT1 respectively to a source area and a drain area of the first active layer ACT1.

The first gate electrode GAT1 is disposed on the first gate insulation layer GI1 in such a way that the first gate electrode GAT1 overlaps a channel area of the first active layer ACT1. For example, the first gate electrode GAT1 may be comprised of one or more of copper (Cu), aluminum (Al), molybdenum (Mo), nickel (Ni), titanium (Ti), chromium (Cr) or an alloy thereof, but not limited thereto.

The first interlayer insulation layer 140 is disposed on the first gate electrode GAT1. The first interlayer insulation layer 140 may be disposed across the active area AA and the non-active area NA1, NA2. For example, the first interlayer insulation layer 140 may be formed of a material selected from a silicon oxide layer, a silicon nitride layer, and a silicon oxynitride layer, but not limited thereto. Preferably, the first interlayer insulation layer 140 may be formed of a silicon nitride layer, but not limited thereto. The first interlayer insulation layer 140 is provided with a contact hole for connecting the first source electrode and the first drain electrode of the first thin film transistor TFT1 respectively to the source area and the drain area of the first active layer ACT1.

The storage capacitor Cst comprises a first capacitor electrode CE1 and a second capacitor electrode CE2. The first capacitor electrode CE1 is disposed on the first gate insulation layer GI1. For example, the first capacitor electrode CE1 may be comprised of one or more of copper (Cu), aluminum (Al), molybdenum (Mo), nickel (Ni), titanium (Ti), chromium (Cr) or an alloy thereof, but not limited thereto. Preferably, the first capacitor electrode CE1 may be formed via the same processing as the first gate electrode GAT1 disposed on the first gate insulation layer GI1. Accordingly, the first capacitor electrode CE1 may be comprised of the same material as the first gate electrode GAT1.

The second capacitor electrode CE2 is disposed to overlap the first capacitor electrode CE1, with the first interlayer insulation layer 140 between the second capacitor electrode CE2 and the first capacitor electrode CE1. For example, the second capacitor electrode CE2 may be comprised of one or more of copper (Cu), aluminum (Al), molybdenum (Mo), nickel (Ni), titanium (Ti), chromium (Cr) or an alloy thereof, but not limited thereto.

The intermediate buffer layer 150 is disposed on the second capacitor electrode CE2. The intermediate buffer layer 150 may be disposed across the active area AA and the non-active area NA1, NA2. The intermediate buffer layer 150 insulates the second capacitor electrode CE2 from the second active layer ACT2. Additionally, the intermediate buffer layer 150 planarizes the upper portion of the storage capacitor Cst. For example, the intermediate buffer layer 150 may be formed of a material selected from a silicon oxide layer, a silicon nitride layer and a silicon oxynitride layer, but not limited thereto. The intermediate buffer layer 150 may have a single-layered structure or a multi-layered structure. Preferably, the intermediate buffer layer 150 may have a multi-layered structure in which a silicon oxide layer and a silicon nitride layer are stacked, but not be limited thereto. The intermediate buffer layer 150 is provided with a contact hole for connecting the first source electrode and the first drain electrode of the first thin film transistor TFT1 respectively to the source area and the drain area of the first active layer ACT1.

The second active layer ACT2 of the second thin film transistor TFT2 is disposed on the intermediate buffer layer 150. For example, the second active layer ACT2 comprises a metal oxide. For example, the second active layer ACT2 may be formed of a metal oxide semiconductor such as indium gallium zinc oxide (IGZO) and the like, but not limited thereto.

A second gate insulation layer GI2 is disposed on the second active layer ACT2. For example, the second gate insulation layer GI2 may be formed of a material selected from a silicon oxide layer, a silicon nitride layer and a silicon oxynitride layer, but not limited thereto. The second gate insulation layer GI2 may have a single-layered structure or a multi-layered structure. The second gate insulation layer GI2 may be formed of a silicon oxide layer with low hydrogen content, but not limited thereto. The second gate insulation layer GI2 is provided with a contact hole for connecting the first source electrode and the first drain electrode of the first thin film transistor TFT1 respectively to the source area and the drain area of the first active layer ACT1, and a contact hole for connecting the second source electrode SE2 and the second drain electrode DE2 respectively to a source area and a drain area of the second active layer ACT2.

The second gate electrode GAT2 is disposed on the second gate insulation layer GI2. The second gate electrode GAT2 is disposed on the second gate insulation layer GI2 in such a way that the second gate electrode GAT2 overlaps a channel area of the second active layer ACT2. For example, the second gate electrode GAT2 may be comprised of one or more of copper (Cu), aluminum (Al), molybdenum (Mo), nickel (Ni), titanium (Ti), chromium (Cr) or an alloy thereof, but not limited thereto. For example, the second gate electrode GAT2 may have a multi-layered structure in which a molybdenum (Mo) layer and a titanium (Ti) layer are stacked, but not be limited thereto.

The second interlayer insulation layer 160 is disposed on the second gate electrode GAT2. The second interlayer insulation layer 160 may be disposed across the active area AA and the non-active area NA1, NA2. For example, the second interlayer insulation layer 160 may be formed of a material selected from a silicon oxide layer, a silicon nitride layer and a silicon oxynitride layer, but not limited thereto. Preferably, the second interlayer insulation layer 160 may have a multi-layered structure in which a silicon nitride layer and a silicon oxide layer are stacked, but not be limited thereto. The second interlayer insulation layer 160 is provided with a contact hole for connecting the first source electrode and the first drain electrode of the first thin film transistor TFT1 respectively to the source area and the drain area of the first active layer ACT1, and a contact hole for connecting the second source electrode SE2 and the second drain electrode DE2 respectively to the source area and the drain area of the second active layer ACT2.

The first source electrode SE1, the first drain electrode DE1, the second source electrode SE2, the second drain electrode DE2 and a first connection electrode CNE1 are disposed on the second interlayer insulation layer 160. The first source electrode SE1 and the first drain electrode DE1 are disposed in such a way that the first source electrode SE1 and the first drain electrode DE1 connect to the source area and the drain area of the first active layer ACT1 respectively through the contact hole, and the second source electrode SE2 and the second drain electrode DE2 are disposed in such a way that the second source electrode SE2 and the second drain electrode DE2 connect to the source area and the drain area of the second active layer ACT2 respectively through the contact hole. The first connection electrode CNE1 is disposed to connect to the second capacitor electrode CE2 of the storage capacitor Cst. The first connection electrode CNE1 connects to the second capacitor electrode CE2 through the contact hole formed at the intermediate buffer layer 150, the second gate insulation layer GI2 and the second interlayer insulation layer 160. Additionally, the first connection electrode CNE1 may be disposed on the second interlayer insulation layer 160 in such a way that the first connection electrode CNE1 connects to the second source electrode SE2 or the second drain electrode DE2. In the drawing, the first connection electrode CNE1 connects to the second source electrode SE2, but is not limited thereto. Also, the first connection electrode CNE1 may connect to the second drain electrode DE2.

For example, the first source electrode SE1, the first drain electrode DE1, the second source electrode SE2, the second drain electrode DE2 and the first connection electrode CNE1 may be comprised of one or more of copper (Cu), aluminum (Al), molybdenum (Mo), nickel (Ni), titanium (Ti), chromium (Cr) or an alloy thereof, but not limited thereto. For example, the first source electrode SE1, the first drain electrode DE1, the second source electrode SE2, the second drain electrode DE2 and the first connection electrode CNE1 may have a single-layered structure or a multi-layered structure. For example, the first source electrode SE1, the first drain electrode DE1, the second source electrode SE2, the second drain electrode DE2 and the first connection electrode CNE1 may have a triple-layered structure in which a titanium (Ti) layer, an aluminum (Al) layer and a titanium (Ti) layer are stacked, but not be limited thereto. The first source electrode SE1, the first drain electrode DE1, the second source electrode SE2, the second drain electrode DE2 and the first connection electrode CNE1 may be formed at the same time in the same process. Accordingly, the first source electrode SE1, the first drain electrode DE1, the second source electrode SE2, the second drain electrode DE2 and the first connection electrode CNE1 may be comprised of the same material.

The first planarization layer PLN1 is disposed to cover the first source electrode SE1, the first drain electrode DE1, the second source electrode SE2, the second drain electrode DE2 and the first connection electrode CNE1. The first planarization layer PLN1 is disposed in the active area AA, and when necessary, the first planarization layer PLN1 may also be disposed in at least a portion of the non-active area NA1, NA2 selectively. The first planarization layer PLN1 planarizes the upper portions of the first thin film transistor TFT1 and the second thin film transistor TFT2. The first planarization layer PLN1 may be formed of an organic insulation material. For example, the first planarization layer PLN1 may be formed of an organic insulation material such as polyimide, photo acryl and the like. The first planarization layer PLN1 may comprise a contact hole for electrically connecting the second source electrode or the second drain electrode DE2 to a second connection electrode CNE2.

The second connection electrode CNE2 is disposed on the first planarization layer PLN1. The second connection electrode CNE2 electrically connects the second source electrode SE2 or the second drain electrode DE2 to an anode 171 of the organic light emitting diode 170 through the contact hole. For example, the second connection electrode CNE2 may be comprised of one or more of copper (Cu), aluminum (Al), molybdenum (Mo), nickel (Ni), titanium (Ti), chromium (Cr) or an alloy thereof, but not limited thereto. For example, the second connection electrode CNE2 may have a triple-layered structure in which a titanium (Ti) layer, an aluminum (Al) layer and a titanium (Ti) layer are stacked, but not be limited thereto.

The second planarization layer PLN2 is disposed on the second connection electrode CNE2. The second planarization layer PLN2 is disposed to cover the second connection electrode CNE2. The second planarization layer PLN2 may be disposed across the active area AA and the non-active area NA1, NA2. The second planarization layer PLN2 planarizes the upper portion of the second connection electrode CNE2. The second planarization layer PLN2 may be formed of an organic insulation material. For example, the second planarization layer PLN2 may be formed of an organic insulation material such as polyimide, photo acryl and the like. The second planarization layer PLN2 may comprise a contact hole for electrically connecting the second connection electrode CNE2 to the anode 171 of the organic light emitting diode 170.

The organic light emitting diode 170 is disposed on the second planarization layer PLN2. The organic light emitting diode 170 comprises an anode 171, an organic light emitting layer 172 and a cathode 173. The organic light emitting diode 170 may be embodied based on a top emission method or a bottom emission method. In the present disclosure, an organic light emitting diode 170 embodied based on the top emission method is described for convenience of description, for example, but not limited thereto.

The anode 171 is disposed on the second planarization layer PLN2. The anode 171 electrically connects to the second source electrode SE2 or the second drain electrode DE2 of the second thin film transistor TFT2 through the contact hole of the second planarization layer PLN2 and the second connection electrode CNE2. The anode 171 may be comprised of a conductive material of a high work function to provide a hole to the organic light emitting layer 172. For example, the anode 171 may comprise a transparent conductive material such as Indium Tin Oxide (ITO), Indium Zin Oxide (IZO) and the like, but not be limited thereto. The anode 171 may have a single-layered structure or a multi-layered structure. In the case where the organic light emitting diode 170 is embodied based on the top emission method, the anode 171 may comprise a reflective layer for reflecting light emitted from the organic light emitting layer 172 toward the cathode 173. The reflective layer may comprise a material having excellent reflectivity such as aluminum (Al) or silver (Ag), but not be limited thereto. For example, the anode 171 may have a triple-layered structure in which indium tin oxide (ITO), silver (Ag) and indium tin oxide (ITO) are stacked, but not be limited thereto.

A bank BNK is disposed on the second planarization layer PLN2 and the anode 171. The bank BNK is disposed on the second planarization layer PLN2 in such a way that at least a part of the anode 171 is exposed. That is, the bank BNK may be disposed on the second planarization layer PLN2 to cover the edge of the anode 171. The bank BNK is an insulation layer disposed between the plurality of sub pixels, to distinguish the plurality of sub pixels. The bank BNK may be formed of an organic insulation material. For example, the bank BNK may be comprised of a polyimide, acryl or benzocyclobutene (BCB)-based resin, but not limited thereto.

A spacer SP may be selectively disposed on the bank BNK, when necessary. The spacer SP may prevent a mask from sagging in the process where the organic light emitting layer 172 is formed, and accordingly, prevent the inflow of foreign substances, and the like.

The organic light emitting layer 172 is disposed on the anode 171. The organic light emitting layer 172 may be an organic layer for emitting light of a specific color. The organic light emitting layer 172 may be formed into a single layer that continues across the front surface of the active area AA. That is, the organic light emitting layer 172 may be a common layer that is formed commonly in the plurality of sub pixels. In another example, the organic light emitting layer 172 may be patterned to correspond to each of the plurality of sub pixels. Also, the organic light emitting layer 172 may further comprise a variety of layers such as a hole transport layer, a hole injection layer, a hole blocking layer, an electron injection layer, an electron blocking layer, an electron transport layer and the like.

The cathode 173 may be disposed on the organic light emitting layer 172. The cathode 173 may be formed into a single layer that continues across the front surface of the active area AA. That is, the cathode 173 may be a common layer that is commonly formed in the plurality of sub pixels. Since the cathode 173 provides electrons to the organic light emitting layer 172, the cathode 173 may be comprised of a conductive material of a low work function. For example, the cathode 173 may be formed of a transparent conductive material such as Indium Tin Oxide (ITO), Indium Zin Oxide (IZO) and the like, or metal such as magnesium (Mg), silver (Ag) and the like or an alloy comprising the same, and the like, and further comprise a metal-doped layer, but not be limited thereto.

A capping layer may be further disposed on the cathode 173. The caping layer prevents the cathode 173 from being degrading. Additionally, the capping layer may reduce loss of light, which is caused in the process where light emitted from the organic light emitting layer 172 is reflected repeatedly between the anode 171 and the cathode 173, thereby enhancing light emission efficiency and ensuring a decrease in electricity consumption.

The encapsulation layer Encp is disposed on the organic light emitting diode 170. The encapsulation layer Encp may be disposed across the active area AA and the non-active area NA1, NA2. The encapsulation layer Encp protects the organic light emitting diode 170 from moisture or foreign substances and the like infiltrating from the outside of the display device 100. The encapsulation layer Encp may have a triple-layered structure in which a first inorganic encapsulation layer Encp1, an organic encapsulation layer Encp2, and a second inorganic encapsulation layer Encp3 are included, but not be limited thereto. The first inorganic encapsulation layer Encp1 is disposed on the cathode 173, the organic encapsulation layer Encp2 is disposed on the first inorganic encapsulation layer Encp1, and the second inorganic encapsulation layer Encp3 is disposed on the organic encapsulation layer Encp2.

The first inorganic encapsulation layer Encp1 is disposed on the cathode 173, and suppresses the infiltration of moisture or oxygen and prevents the oxidation of the cathode 173. For example, the first inorganic encapsulation layer Encp1 may be formed of an inorganic insulation material such as a silicon nitride layer, a silicon oxide layer, a silicon oxynitride layer, an aluminum oxide layer and the like, but not limited thereto.

The organic encapsulation layer Encp2 is disposed on the first inorganic encapsulation layer Encp1 and planarizes the surface of the first inorganic encapsulation layer Encp1. The organic encapsulation layer Encp2 is formed to be thicker than the first inorganic encapsulation layer Encp1. Accordingly, the organic encapsulation layer Encp2 may be a foreign substance cover layer covering foreign substances that may be generated in processing. For example, the organic encapsulation layer Encp2 may be comprised of an organic insulation material such as silicon oxycarbon, acrylic resin, epoxy resin and the like, but not limited thereto.

The second inorganic encapsulation layer Encp3 may be disposed on the organic encapsulation layer Encp2 and suppress the infiltration of moisture or oxygen. The second inorganic encapsulation layer Encp3 suppresses the infiltration of moisture or oxygen from the outside into the organic light emitting diode 170. For example, the second inorganic encapsulation layer Encp3 may be formed of an inorganic insulation material such as a silicon nitride layer, a silicon oxide layer, a silicon oxynitride layer, an aluminum oxide layer and the like, but not limited thereto.

The optical film 180 is disposed on the second inorganic encapsulation layer Encp3. The optical film 180 may be bonded onto the second inorganic encapsulation layer Encp3 by the adhesive layer ADH. The optical film 180 and the adhesive layer ADH may be disposed across the active area AA and the non-active area NA1, NA2. The optical film 180 may minimize the loss of light emitted from the organic light emitting diode 170, and minimize reflection caused by external light, to enhance light emission efficiency. For example, the optical film 180 may be a polarization plate, but not limited thereto. The adhesive layer ADH may be selected from an optical clear adhesive (OCA), an optical clear resin (OCR), and a pressure sensitive adhesive (PSA), for example, but not limited thereto.

Hereinafter, the non-active area NA1, NA2 comprising a through hole TH is specifically described with reference to FIGS. 2 and 4. FIG. 4 shows an example of the structure of a cross section of the first non-active area NA1, but the structure may also be applied to the second non-active area NA2. For convenience of description, the structure of the cross section of the first non-active area NA1 is described as an example.

The first non-active area NA1 comprises the through hole TH and a surrounding area SA surrounding the through hole TH. In the first non-active area NA1, the substrate buffer layer 120, the active buffer layer 130, the first gate insulation layer GI1, the first interlayer insulation layer 140, the intermediate buffer layer 150, the second interlayer insulation layer 160, the second planarization layer PLN2, the encapsulation layer Encp, the adhesive layer ADH and the optical film 180 may be disposed on the substrate 110. The through hole TH is formed in such a way that the through hole TH passes through the substrate 110, the substrate buffer layer 120, the active buffer layer 130, the first gate insulation layer GI1, the first interlayer insulation layer 140, the intermediate buffer layer 150, the second interlayer insulation layer 160, the second planarization layer PLN2, the encapsulation layer Encp, the adhesive layer ADH and the optical film 180. That is, the substrate 110, the substrate buffer layer 120, the active buffer layer 130, the first gate insulation layer GI1, the first interlayer insulation layer 140, the intermediate buffer layer 150, the second interlayer insulation layer 160, the second planarization layer PLN2, the encapsulation layer Encp, the adhesive layer ADH and the optical film 180 are disposed in a surrounding area SA of the first non-active area NA1.

In the surrounding area SA, a dam DAM may be disposed. The dam DAM adjusts the flow of an organic insulation material at a time when the organic encapsulation layer Encp2 is formed. The dam DAM is disposed in the surrounding area SA in such a way that the dam DAM surrounds the through hole TH. The dam DAM may be shaped into a closed curve that surrounds the outer side of the through hole TH. In the drawing, one dam DAM is provided, but not limited thereto. When necessary, two or more dams DAM may be provided. The dam DAM may have a single-layered structure or a multi-layered structure. For example, the dam DAM may have a multi-layered structure in which a first layer DAM-1, a second layer DAM-2 and a third layer DAM-3 are stacked. Specifically, the first layer DAM-1 may be formed of the same material as the second interlayer insulation layer 160 in the same process as the second interlayer insulation layer 160, the second layer DAM-2 may be formed of the same material as the second planarization layer PLN2 in the same process as the second planarization layer PLN2, and the third layer DAM-3 may be formed of the same material as the bank BNK in the same process as the bank BNK, but the present disclosure is not limited thereto.

The second interlayer insulation layer 160 disposed in the surrounding area SA has a convex and concave structure. The second interlayer insulation layer 160 may have a disconnection (or disconnected) structure because of the convex and concave structure. That is, the second interlayer insulation layer 160 disposed in the surrounding area SA may comprise a plurality of openings that passes through the second interlayer insulation layer 160 in the thickness direction thereof. Accordingly, even if moisture or oxygen infiltrates through the through hole TH, the infiltration of the moisture toward the active area AA may be prevented and delayed.

In the surrounding area SA, the second planarization layer PLN2 is disposed on the second interlayer insulation layer 160. The second planarization layer PLN2 disposed in the surrounding area SA has a convex and concave structure. The second planarization layer PLN2 may have a disconnection (or disconnected) structure because of the convex and concave structure. That is, the second planarization layer PLN2 disposed in the surrounding area SA may comprise a plurality of openings that passes through the second planarization layer PLN2 in the thickness direction thereof. Accordingly, even if moisture or oxygen infiltrates through the through hole TH, the infiltration of the moisture toward the active area AA may be prevented and delayed.

The infiltration of moisture may be prevented by the convex and concave structures of the second interlayer insulation layer 160 and the second planarization layer PLN2 disposed in the surrounding area SA adjacent to the through hole TH. Accordingly, the deterioration of interfacial adhesion, caused by the infiltration of moisture, may be minimized. In particular, since the second planarization layer PLN2 formed of an organic material, and the second interlayer insulation layer 160 formed of an inorganic material have opposite physical properties, the adhesion of the interface between the second planarization layer PLN2 and the second interlayer insulation layer 160 may deteriorate easily, at a time of infiltration of moisture. The convex and concave structures formed at the second planarization layer PLN2 and the second interlayer insulation layer 160 may prevent and minimize the progress of the infiltration of moisture, thereby preventing the deterioration of interfacial adhesion and enhancing the reliability of the display device 100.

The convex and concave structure of the second interlayer insulation layer 160 and the convex and concave structure of the second planarization layer PLN2 may be formed to overlap each other respectively. That is, each of the plurality of openings formed at the second interlayer insulation layer 160 may be disposed to overlap a respective one of the plurality of openings formed at the second planarization layer PLN2.

As described above, the encapsulation layer Encp comprises the first inorganic encapsulation layer Encp1, the organic encapsulation layer Encp2 and the second inorganic encapsulation layer Encp3. The first inorganic encapsulation layer Encp1 is disposed on the second planarization layer PLN2. The first inorganic encapsulation layer Encp1 is disposed to cover the second planarization layer PLN2 and the dam DAM. The first inorganic encapsulation layer Encp1 may be formed into a disconnection (or disconnected) structure without connecting as one layer, because of the convex and concave structure formed at each of the second interlayer insulation layer 160 and the second planarization layer PLN2.

The organic encapsulation layer Encp2 is disposed on the first inorganic encapsulation layer Encp1. The organic encapsulation layer Encp2 may be disposed to fill each of the plurality of openings formed at the second interlayer insulation layer 160 and each of the plurality of openings formed at the second planarization layer PLN2.

At least a part of the organic encapsulation layer Encp2 disposed in the surrounding area SA adjacent to the through hole TH is provided in such a way that the thickness thereof decreases toward the through hole TH. The thickness of the organic encapsulation layer Encp2 may be defined as a straight line distance from the upper surface of the second planarization layer PLN2 to the upper surface of the organic encapsulation layer Encp2, in the surrounding area SA. The organic encapsulation layer Encp2 in the surrounding area SA decreases gradually toward the through hole TH. Accordingly, the organic encapsulation layer Encp2 disposed in the surrounding area SA adjacent to the through hole TH is structured to incline from the upper surface thereof (i.e., the upper surface of the organic encapsulation layer Encp2) toward the substrate 110.

The second inorganic encapsulation layer Encp3 is disposed on the organic encapsulation layer Encp2. Accordingly, in the surrounding area SA adjacent to the through hole TH, the second inorganic encapsulation layer Encp3 is structured to incline along the inclined upper surface of the organic encapsulation layer Encp2. The second inorganic encapsulation layer Encp3 may be disposed along the inclined upper surface of the organic encapsulation layer Encp2, with a constant thickness.

The optical film 180 is bonded onto the second inorganic encapsulation layer Encp3 using the adhesive layer ADH. The adhesive layer ADH is disposed to contact the upper surface of the second inorganic encapsulation layer Encp3. The optical film 180 is disposed to contact the upper surface of the adhesive layer ADH. Accordingly, each of the adhesive layer ADH and the optical film 180 disposed in the surrounding area SA adjacent to the through hole TH is structured to incline toward the substrate 110 along the inclined upper surface of the second inorganic encapsulation layer Encp3.

Since the organic encapsulation layer Encp2 disposed in the surrounding area SA adjacent to the through hole TH is formed in such a way that the thickness thereof (i.e., the thickness of the organic encapsulation layer Encp2) decreases gradually, stress applied to the layers under the organic encapsulation layer Encp2 may decrease. The shrinkage rate of the adhesive layer ADH and the optical film 180 disposed on the encapsulation layer Encp is greater than the shrinkage rate of the encapsulation layer Encp. In a reliability test, the adhesive layer ADH and the optical film 180 may easily shrink under the conditions of high temperature and high humidity. For example, the adhesive layer ADH and the optical film 180 may shrink from the surrounding area SA toward the active area AA. As the adhesive layer ADH and the optical film 180 shrink as described above, stress may be applied to the layers disposed under the organic encapsulation layer Encp2. At this time, the interfaces of the second interlayer insulation layer 160 and the second planarization layer PLN2 having relatively low interfacial adhesion may be separated and torn out by the stress. However, in the display device 100 of an example embodiment, the organic encapsulation layer Encp2 of the encapsulation layer Encp disposed in the surrounding area SA adjacent to the through hole TH is formed in such a way that the thickness of the organic encapsulation layer Encp2 decreases toward the through hole TH. Since the thickness of the organic encapsulation layer Encp2 adjacent to the through hole TH decreases as described above, stress applied to the layers under the organic encapsulation layer Encp2 may decrease easily. Thus, the separation or torn-out of an interface may be minimized, and a reliable display device 100 may be provided.

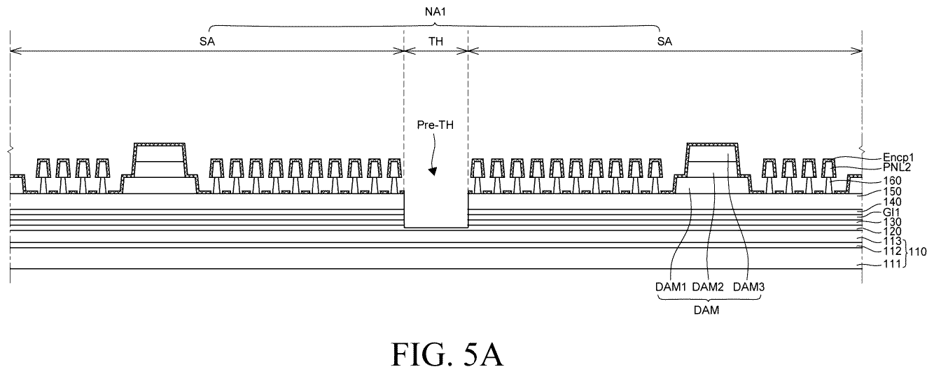

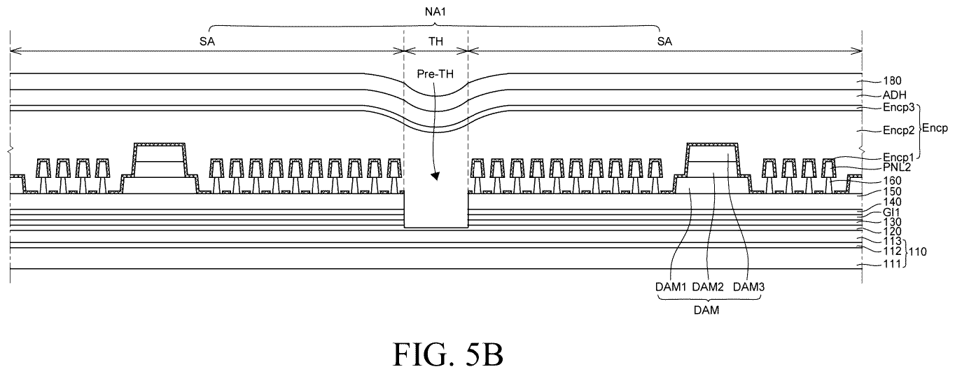

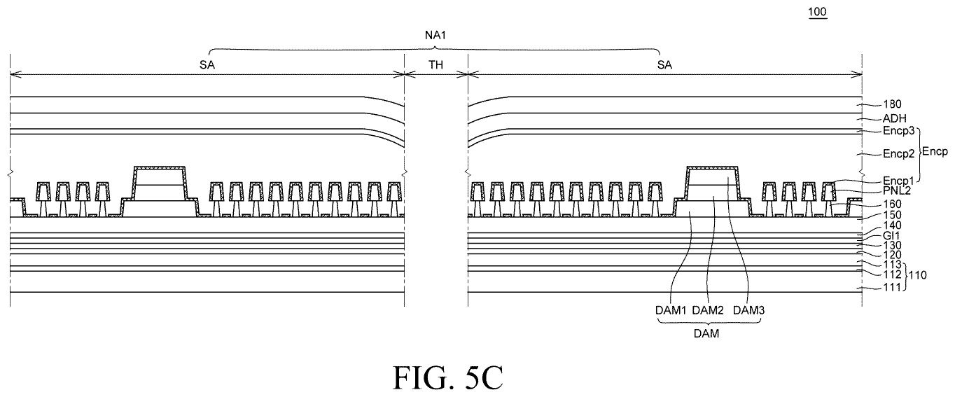

Hereinafter, a part of the process of manufacturing a display device of an example embodiment is described with reference to FIGS. 5A to 5C. FIGS. 5A to 5C are cross-sectional views for describing a manufacturing method of a non-active area in the display device of an example embodiment.

Referring to FIG. 5A, the active buffer layer 130, the substrate buffer layer 120, the active buffer layer 130, the first gate insulation layer GI1, the first interlayer insulation layer 140, the intermediate buffer layer 150 and the second interlayer insulation layer 160 are consecutively stacked on the substrate 110. Then the second interlayer insulation layer 160 is patterned such that convex and concave structures of the first layer DAM-1 of the dam DAM and the second interlayer insulation layer 160 are formed. Then the second planarization layer PLN2 is stacked on the second interlayer insulation layer 160 and patterned, such that convex and concave structures of the second layer DAM-2 of the dam DAM and the second planarization layer PLN2 are formed. Then the bank BNK is stacked and patterned such that the third layer DAM-3 of the dam DAM is formed. Then the first inorganic encapsulation layer Encp1 is stacked. After the first inorganic encapsulation layer Encp1 is stacked, a pre-through hole Pre-TH is formed in such a way that the pre-through hole Pre-TH passes through the first inorganic encapsulation layer Encp1, the second planarization layer PLN2, the second interlayer insulation layer 160, the intermediate buffer layer 150, the first interlayer insulation layer 140, the first gate insulation layer GI1, and the active buffer layer 130 that are stacked at a position where the through hole TH is to be formed in the non-active area NA1, and passes through at least a part of the substrate buffer layer 120 that is stacked at the position where the through hole TH is to be formed in the non-active area NA1. For example, the pre-through hole Pre-TH may be formed in such a way that the layers are all etched at a time after the layers from the substrate buffer layer 120 to the first inorganic encapsulation layer Encp1 are stacked, or in such a way that a process of forming and etching one layer is repeated.

Referring to FIG. 5B, the organic encapsulation layer Encp2 is stacked on the first inorganic encapsulation layer Encp1 to fill the pre-through hole Pre-TH. At this time, as the organic encapsulation layer Encp2 fills the pre-through hole Pre-TH, the organic encapsulation layer Encp2 is provided with a valley-looking groove at the pre-through hole Pre-TH portion. Then the second inorganic encapsulation layer Encp3 is stacked on the organic encapsulation layer Encp2, the adhesive layer ADH is applied onto the second inorganic encapsulation layer Encp3, and the optical film 180 is attached to the adhesive layer ADH. At this time, each of the second inorganic encapsulation layer Encp3, the adhesive layer ADH and the optical film 180 is provided with a valley-looking groove at the pre-through hole Pre-TH portion to correspond to the groove formed at the organic encapsulation layer Encp2. Accordingly, each of the organic encapsulation layer Encp2, the second inorganic encapsulation layer Encp3, the adhesive layer ADH and the optical film 180 have a structure inclining toward the substrate 110, at a portion adjacent to the pre-through hole Pre-TH.

Referring to FIG. 5C, the through hole TH is formed by etching all the components stacked at the pre-through hole Pre-TH portion with a laser. Accordingly, the organic encapsulation layer Encp2 disposed in the surrounding area SA adjacent to the through hole TH is formed in such a way that the thickness of the organic encapsulation layer Encp2 decreases toward the through hole TH. Thus, the organic encapsulation layer Encp2 disposed in the surrounding area SA adjacent to the through hole TH is structured to incline from the upper surface thereof toward the substrate 110. Further, each of the second inorganic encapsulation layer Encp3, the adhesive layer ADH and the optical film 180 stacked on the organic encapsulation layer Encp2 is structured to incline along the inclined upper surface of the organic encapsulation layer Encp2.

The manufacturing process described with reference to FIGS. 5A to 5C is provided as an example for obtaining the cross-sectional structure illustrated in FIG. 4, but not limited thereto.

As described above, in the display device 100 of an example embodiment, each of the second interlayer insulation layer and the second planarization layer disposed in the area adjacent to the through hole has a convex and concave structure, to delay infiltration of moisture. Additionally, the organic encapsulation layer disposed in the surrounding area is provided in such a way that the thickness thereof decreases toward the through hole. Accordingly, stress applied to the layers disposed under the adhesive layer and the optical film, caused by the shrinkage of the adhesive layer and the optical film, may decrease. Thus, in the display device 100 of an example embodiment, the separation or torn-out of an interface and the like between the second interlayer insulation layer and the second planarization layer, caused by infiltration of moisture, may be minimized in a reliability test, thereby providing a display device having excellent reliability.

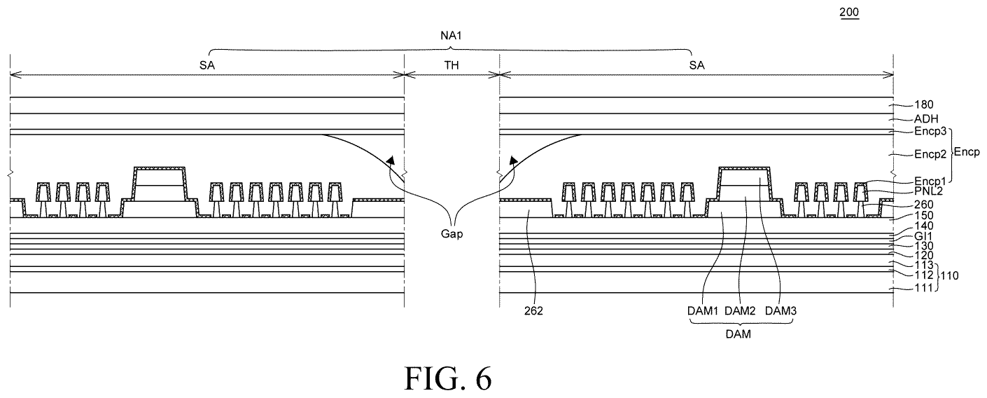

FIG. 6 is a cross-sectional view of a first non-active area in a display device of another example embodiment. A display device 200 illustrated in FIG. 6 is substantially the same as the display device 100 illustrated in FIGS. 1 to 4, except that the display device 200 further comprises a width of a through hole, a disposition structure of an encapsulation layer and an adhesive layer, and a gap further comprised in a surrounding area adjacent to the through hole and that a second insulation layer comprises a planarization part. In this context, the description of their common features may be omitted for brevity.

Referring to FIG. 6, in the display device 200 of another example embodiment, at least a part of a second interlayer insulation layer 260 disposed in the surrounding area SA comprises a convex and concave structure. The second interlayer insulation layer 260 may have a disconnection (or disconnected) structure because of the convex and concave structure. That is, the second interlayer insulation layer 260 disposed in the surrounding area SA may comprise a plurality of openings that passes through the second interlayer insulation layer 260 in the thickness direction thereof. Accordingly, even if moisture or oxygen infiltrates through the through hole TH, the progress of the infiltration of the moisture toward the active area AA may be prevented or delayed.

In at least a partial area of the second interlayer insulation layer 260 disposed in the surrounding area SA adjacent to the through hole TH, a planarization part 262 is provided. The planarization part 262 is not provided with a convex and concave structure, but has a planar upper surface. That is, at least a partial area of the second interlayer insulation layer 260 disposed in the surrounding area SA adjacent to the through hole TH does not comprise a convex and concave structure.

In the surrounding area SA, a second planarization layer PLN2 is disposed on the second interlayer insulation layer 260. The second planarization layer PLN2 is not disposed on the planarization part 262 of the second interlayer insulation layer 260. That is, in the surrounding area SA, the second planarization layer PLN2 is disposed on the second interlayer insulation layer 260, except for the planarization part 262 of the second interlayer insulation layer 260.

According to one or more aspects of the present disclosure, in the case where the reliability of a display device is tested under harsh conditions such as high temperature and high humidity, after the display device is manufactured, it is found that the separation and torn-out of an interface between the second interlayer insulation layer and the second planarization layer having a convex and concave structure respectively occur frequently in the surrounding area SA adjacent to the through hole TH.

To prevent this from happening, in the display device 200 of another example embodiment, while a convex and concave structure is provided in at least a partial area of the second interlayer insulation layer 260 disposed in the surrounding area SA, the planarization part 262 is provided in the remaining area disposed in the surrounding area SA adjacent to the through hole TH. Additionally, the second planarization layer PLN2 is formed in such a way that the second planarization layer PLN2 is disposed on the second interlayer insulation layer 260, except for the planarization part 262. Accordingly, at a time when reliability is tested at high temperature and high humidity, since interfacial adhesion in the surrounding area SA adjacent to the through hole TH does not deteriorate, failure such as the separation and torn-out of an interface may decrease.

For example, the planarization part 262 may be formed in an area corresponding to a depth of 1 μm to 10 μm from the through hole TH toward the active area AA, but not limited thereto. At this time, a disconnection caused by the convex and concave structure may help to minimize the infiltration of moisture, and in a reliability test, the separation or torn-out and the like of an interface may decrease effectively.

An encapsulation layer Encp is disposed on the second planarization layer PLN2. The encapsulation layer Encp comprises a first inorganic encapsulation layer Encp1, an organic encapsulation layer Encp2, and a second inorganic encapsulation layer Encp3. The first inorganic encapsulation layer Encp1 is disposed to cover the second planarization layer PLN2, the dam DAM and the planarization part 262 of the second interlayer insulation layer 260. The first inorganic encapsulation layer Encp1 may have a disconnection (or disconnected) structure because of the convex and concave structure formed respectively at the second interlayer insulation layer 260 and the second planarization layer PLN2, without connecting as one layer.

The organic encapsulation layer Encp2 is disposed on the first inorganic encapsulation layer Encp1. At least a part of the organic encapsulation layer Encp2 disposed in the surrounding area SA adjacent to the through hole TH is provided in such a way that the thickness thereof decreases toward the through hole TH. The thickness of the organic encapsulation layer Encp2 decreases gradually toward the through hole TH. Accordingly, the organic encapsulation layer Encp2 disposed in the surrounding area SA adjacent to the through hole TH is structured to incline from the upper surface thereof toward the substrate 110. Thus, stress applied to the layers disposed under the organic encapsulation layer Encp2 may decrease, and failure such as the separation or torn-out of an interface, caused by stress, may be prevented.

The second inorganic encapsulation layer Encp3 is disposed on the organic encapsulation layer Encp2. The second inorganic encapsulation layer Encp3 is disposed to contact a planar upper surface of the organic encapsulation layer Encp2 while the second inorganic encapsulation layer Encp3 is disposed not to contact an inclined upper surface of the organic encapsulation layer Encp2. Accordingly, a gap Gap is included between the inclined upper surface of the organic encapsulation layer Encp2 and the second inorganic encapsulation layer Encp3. The second inorganic encapsulation layer Encp3 may be disposed planarly without being structured to incline, in the surrounding area SA adjacent to the through hole TH.

The optical film 180 is bonded onto the second inorganic encapsulation layer Encp3 using the adhesive layer ADH. The adhesive layer ADH and the optical film 180 are disposed planarly without being structured to incline like the second inorganic encapsulation layer Encp3.

In the case where the gap Gap is formed between the inclined upper surface of the organic encapsulation layer Encp2 and the second inorganic encapsulation layer Encp3 as described above, the accumulation of stress, caused by the shrinkage of the adhesive layer ADH and the optical film 180, to the layers disposed under the adhesive layer ADH and the optical film 180 may be prevented. Accordingly, failure such as the separation or torn-out of an interface, caused by stress, may be suppressed further.

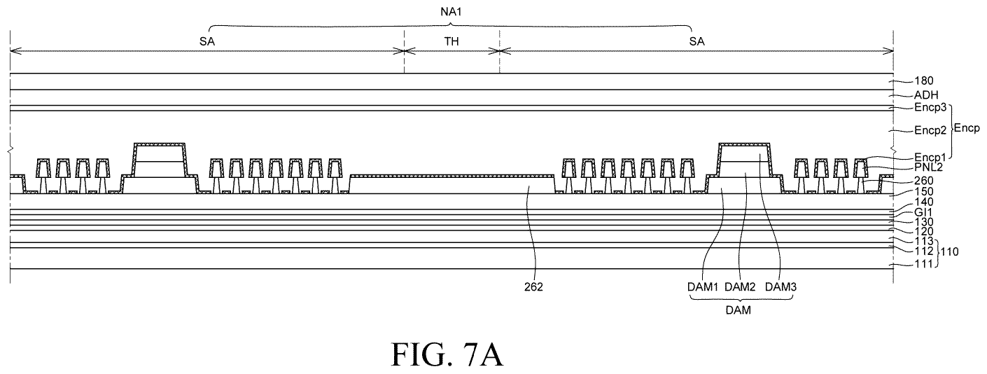

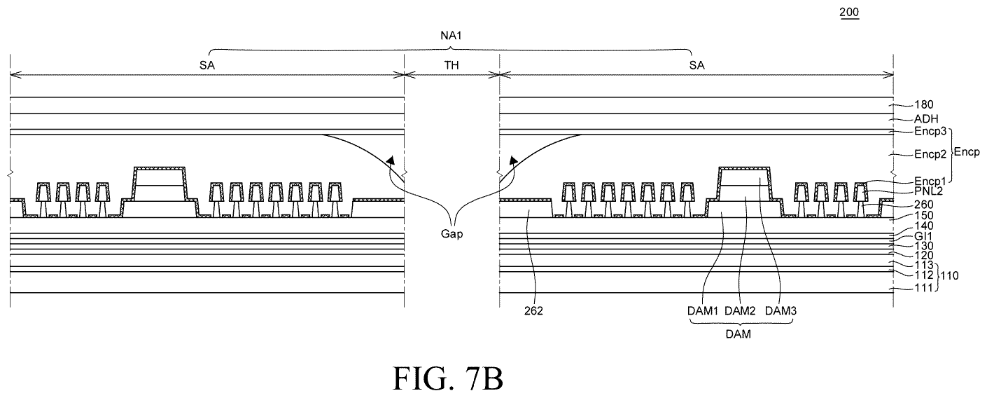

Hereinafter, a manufacturing method of the displayed device 200 illustrated in FIG. 6 is described with reference to FIGS. 7A and 7B. FIGS. 7A and 7B are cross-sectional views for describing a manufacturing method of a non-active area in the display device of another example embodiment.

The display device 100 illustrated in FIGS. 4 and 5A to 5C is manufactured in such a way that the pre-through hole Pre-TH is formed, after stacking up to the first inorganic encapsulation layer Encp1, but the display device 200 illustrated in FIG. 6 is manufactured in such a way that the through hole TH is formed after stacking up to the optical film 180. The display device 200 illustrated in FIGS. 6 and 7A and 7B are similar to the display device 100 illustrated in FIGS. 1 to 4, except for the different descriptions provided for FIGS. 6 and 7A and 7B, and repetitive descriptions may be omitted for brevity.

Specifically, referring to FIG. 7A, the active buffer layer 130, the substrate buffer layer 120, the active buffer layer 130, the first gate insulation layer GI1, the first interlayer insulation layer 140, the intermediate buffer layer 150, and the second interlayer insulation layer 150 are stacked consecutively on the substrate 110. Then the second interlayer insulation layer 260 is patterned to form the convex and concave structures of the first layer DAM-1 and the second interlayer insulation layer 260 of the dam DAM. At this time, a partial area of the second interlayer insulation layer 260, disposed in an area where the through hole TH is to be formed and in a portion of the surrounding area SA adjacent to the through hole TH, does not have a convex and concave structure and is formed planarly. Then the second planarization layer PLN2 is stacked on the second interlayer insulation layer 260, and patterned, to form the second layer DAM-2 of the dam DAM and the convex and concave structure of the second planarization layer PLN2. Then the bank BNK is stacked and patterned, to form the third layer DAM-3 of the dam DAM. Then the first inorganic encapsulation layer Encp1, the organic encapsulation layer Encp2 and the second inorganic encapsulation layer Encp3 are consecutively stacked. Then the optical film 180 is attached onto the second inorganic encapsulation layer Encp3 using the adhesive layer ADH.

Then, referring to FIG. 7B, all the components stacked in the area where the through hole TH is to be formed are etched with a laser to form the through hole TH. Unlike the manufacturing method illustrated in FIGS. 5A to 5C, the manufacturing method illustrated in FIGS. 7A and 7B involves etching all the layers stacked in the area where the through hole TH is formed from the substrate 110 to the optical film 180, at a time, after stacking up to the optical film 180. Etching depth in the display device 1 of FIGS. 5A to 5C is greater than etching depth in the display device 200 of FIGS. 7A and 7B. Accordingly, in the manufacturing method of the display device illustrated in FIGS. 7A and 7B, a through hole TH having a relatively wide width is formed because of over etching since deep etching is needed. Additionally, the organic encapsulation layer Encp2 formed of an organic material is over-etched because of the properties of the material itself. Specifically, in the process where the through hole TH is formed by irradiating a laser, the organic encapsulation layer Encp2 disposed in the surrounding area SA adjacent to the through hole TH is over-etched. Accordingly, the organic encapsulation layer Encp2 disposed in the surrounding area SA adjacent to the through hole TH is structured to incline since the thickness of the organic encapsulation layer Encp2 in the surrounding area SA decreases gradually toward the through hole TH. Thus, a gap Gap is formed between the inclined upper surface of the organic encapsulation layer Encp2 and the second inorganic encapsulation layer Encp3.

The manufacturing method illustrated in FIGS. 5A to 5C involves forming the pre-through hole Pre-TH and then stacking the organic encapsulation layer Encp2, forming a step at the organic encapsulation layer Encp2 in the area where the through hole TH is to be formed, and forming the through hole TH. That is, the manufacturing method illustrated in FIGS. 5A to 5C involves forming the pre-through hole Pre-TH and additionally performing etching later and forming the through hole TH, rather than performing etching at a time (or at one time). Unlike the manufacturing method of FIGS. 5A to 5C, the manufacturing method of FIGS. 7A and 7B involves etching all the layers stacked at the position where the through hole TH is to be formed, at a time (or at one time), and inducing over-etching of the organic encapsulation layer Encp2. Accordingly, in the display device 200 based on the manufacturing method illustrated in FIGS. 7A and 7B, the organic encapsulation layer Encp2 adjacent to the through hole TH may have a greater inclined section and a steeper inclination than in the display device 100 based on the manufacturing method illustrated in FIGS. 5A to 5C. In the manufacturing method illustrated in FIGS. 7A and 7B, a relatively thick organic encapsulation layer Encp2 is applied preferably to prevent damage caused by a laser of high energy in the process where etching is performed at a time.

The manufacturing method described with reference to FIGS. 7A and 7B is provided as an example to obtain a cross-sectional structure illustrated in FIG. 6, but not limited thereto.

The display device 200 of another example embodiment may delay the infiltration of moisture since each of the second interlayer insulation layer and the second planarization layer disposed in the surrounding area has a convex and concave structure. At this time, the second interlayer insulation layer disposed in the surrounding area adjacent to the through hole comprises a planar planarization part without having a convex and concave structure. Accordingly, in a reliability test, the occurrence of failure such as the separation or torn-out of an interface may be suppressed further. Additionally, the organic encapsulation layer disposed in the surrounding area is provided in such a way that the thickness thereof decreases toward the through hole, and a gap is provided among the organic encapsulation layer, the adhesive layer and the optical film. Accordingly, the application of stress, caused by the shrinkage of the adhesive layer and the optical film, to the layers disposed under the adhesive layer and the optical film may be prevented. Thus, the display device 200 of another example embodiment may minimize failure such as the separation or torn-out of an interface, which occurs between the second interlayer insulation layer and the second planarization layer. As a result, a display device ensuring excellent reliability may be provided.

In FIG. 6, a partial area of the second interlayer insulation layer 260 disposed in the surrounding area SA adjacent to the through hole TH comprises a planarization part 262, but not be limited thereto. In another example, the second interlayer insulation layer and the second planarization layer of the display device in FIG. 6 may have the same convex and concave structures as the second interlayer insulation layer and the second planarization layer of the display device in FIG. 4. In yet another example, the organic encapsulation layer Encp2, the second inorganic encapsulation layer Encp3, the adhesive layer ADH and the optical film 180 of the display device 100 in FIG. 4 may be modified to have the same structures as the organic encapsulation layer Encp2, the second inorganic encapsulation layer Encp3, the adhesive layer ADH and the optical film 180 of the display device 200 in FIG. 6.

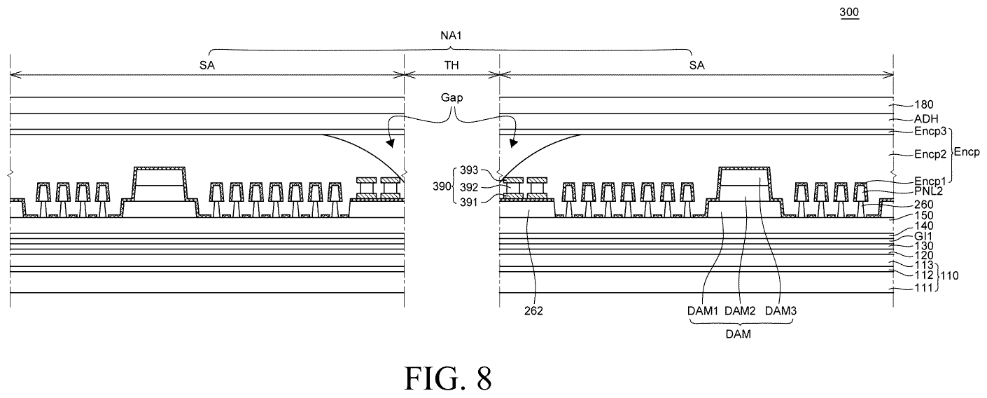

FIG. 8 is a cross-sectional view of a first non-active area in a display device of yet another example embodiment. A display device 300 illustrated in FIG. 8 is substantially the same as the display device 200 illustrated in FIG. 6 except that the display device 300 in FIG. 8 further comprises a metallic convex and concave part. In this context, the description of their common features may be omitted for brevity.

Referring to FIG. 8, an encapsulation layer Encp is disposed on a second planarization layer PLN2. The encapsulation layer Encp comprises a first inorganic encapsulation layer Encp1, an organic encapsulation layer Encp2 and a second inorganic encapsulation layer Encp3.

The first inorganic encapsulation layer Encp1 is disposed on the second planarization layer PLN2. The first inorganic encapsulation layer Encp1 is disposed to cover the second planarization layer PLN2, the damp DAM, and the planarization part 262 of the second interlayer insulation layer 260.

A metallic convex and concave part 390 is disposed on the first inorganic encapsulation layer Encp1 overlapping the planarization part 262 of the second interlayer insulation layer 260. The metallic convex and concave part 390 is a metal-based convex and concave part disposed on the planarization part 262 of the second interlayer insulation layer 260. As the metal convex and concave part 390 is disposed on the planarization part 262 as described above, the interfacial adhesion of the layers disposed on the planarization part 262 improves, thereby further preventing failure such as the separation or torn-out of an interface.

For example, the metallic convex and concave part 390 may be comprised of one or more of copper (Cu), aluminum (Al), molybdenum (Mo), nickel (Ni), titanium (Ti), chromium (Cr) or an alloy thereof, but not limited thereto.

For example, the metallic convex and concave part 390 may have a single-layered structure or a multi-layered structure. For example, the metallic convex and concave part 390 may have a triple-layered structure in which a first metallic layer 391, a second metallic layer 392 and a third metallic layer 393 are stacked consecutively, but not be limited thereto. The first metallic layer 391, the second metallic layer 392 and the third metallic layer 393 of the metallic convex and concave part 390 may be layers formed of the same metal or different metals.

For example, the metallic convex and concave part 390 may be a Ti/Al/Ti triple-layered structure in which the first metallic layer 391 is a titanium (Ti) layer, the second metallic layer 392 is an aluminum (Al) layer, and the third metallic layer 393 is a titanium (Ti) layer, but not limited thereto. At this time, the second metallic layer 392 as an aluminum (Al) layer may have a greater etch rate than the first and third metallic layers 391, 393 as a titanium (Ti) layer. Accordingly, at a time of formation of the metallic convex and concave part 390, the aluminum (Al) layer of a high etch rate is formed to have a width less than that of the titanium (Ti) layer. Thus, in the case where the metallic convex and concave part 390 has a Ti/Al/Ti triple-layered structure, the width of each of the first metallic layer 391 and the third metallic layer 393 as a titanium (Ti) layer may be greater than the width of the second metallic layer 392 as an aluminum (Al) layer.

The metallic convex and concave part provided in the display device 300 illustrated in FIG. 8 may be applied and embodied to the display device 100 illustrated in FIG. 4.

The organic encapsulation layer Encp2 is disposed to cover the first inorganic encapsulation layer Encp1 and the metallic convex and concave part 390. At least a part of the organic encapsulation layer Encp2 in the surrounding area SA adjacent to the through hole TH is provided in such a way that thickness thereof decreases toward the through hole TH. The thickness of the organic encapsulation layer Encp2 decreases toward the through hole TH in the surrounding area SA. Accordingly, the organic encapsulation layer Encp2 disposed in the surrounding area SA adjacent to the through hole TH is structured to incline from the upper surface thereof toward the substrate 110. Thus, stress applied to the layers disposed under the organic encapsulation layer Encp2 may decrease, and the separation or torn-out of an interface, caused by the stress, may be prevented.

The second inorganic encapsulation layer Encp3 is disposed on the organic encapsulation layer Encp2. The second inorganic encapsulation layer Encp3 is disposed not to contact the inclined upper surface of the organic encapsulation layer Encp2, while the second inorganic encapsulation layer Encp3 is disposed to contact the planar upper surface of the organic encapsulation layer Encp2. Accordingly, a gap Gap is included between the inclined upper surface of the organic encapsulation layer Encp2 and the second inorganic encapsulation layer Encp3. The second inorganic encapsulation layer Encp3 may be planarly disposed without being structured to incline, in the surrounding area SA adjacent to the through hole TH.

The optical film 180 is bonded onto the second inorganic encapsulation layer Encp3 using the adhesive layer ADH. Like the second inorganic encapsulation layer Encp3, the adhesive layer ADH and the optical film 180 are disposed planarly without being structured to incline.

In the case where the gap Gap is formed between the inclined upper surface of the organic encapsulation layer Encp2 and the second inorganic encapsulation layer Encp3 as described above, the accumulation of stress, caused by the shrinkage of the adhesive layer ADH and the optical film 180, to the layers disposed under the adhesive layer ADH and the optical film 180 may be prevented. Thus, failure such as the separation or torn-out of an interface, caused by stress, may be suppressed further.

Various examples and aspects of the present disclosure are described below. These are provided as examples, and do not limit the scope of the present disclosure.

According to one or more aspects of the present disclosure, a display device may comprise: a substrate; an active area; a non-active area in the active area; a first interlayer insulation layer disposed on the substrate; a second interlayer insulation layer disposed on the first interlayer insulation layer; at least one planarization layer disposed on the second interlayer insulation layer; and an encapsulation layer disposed on the at least one planarization layer, wherein the non-active area comprises a through hole and a surrounding area surrounding the through hole, at least a part of the second interlayer insulation layer and at least a part of the at least one planarization layer disposed in the surrounding area have a convex and concave structure, at least a part of the encapsulation layer is disposed in the surrounding area adjacent to the through hole in such a way that a thickness of the at least a part of the encapsulation layer decreases toward the through hole.

The encapsulation layer may comprise an inorganic encapsulation layer disposed on the at least one planarization layer and an organic encapsulation layer disposed on the inorganic encapsulation layer, and for the encapsulation layer, at least a part of the organic encapsulation layer may be disposed in the surrounding area adjacent to the through hole in such a way that a thickness of the at least a part of the organic encapsulation layer decreases toward the through hole.

The at least a part of the organic encapsulation layer disposed in the surrounding area adjacent to the through hole may be structured to incline toward the substrate.

The display device may further comprise: a first thin film transistor disposed on the substrate in the active area, and comprising a first active layer, a first gate electrode, a first source electrode and a first drain electrode; a second thin film transistor disposed on the first thin film transistor, and comprising a second active layer, a second gate electrode, a second source electrode and second drain electrode; and an organic light emitting diode disposed on the second thin film transistor, wherein the first interlayer insulation layer may be disposed between the first gate electrode and the second active layer in the active area, and the second interlayer insulation layer may be disposed among the second gate electrode, the second source electrode and the second drain electrode in the active area.

The display device may further comprise an optical film disposed on the encapsulation layer and an adhesive layer disposed between the encapsulation layer and the optical film.

The adhesive layer may be disposed to contact an upper surface of the encapsulation layer, and the adhesive layer and the optical film disposed in the surrounding area adjacent to the through hole may be structured to incline toward the substrate along an inclined upper surface of the organic encapsulation layer.

A gap may be included between an inclined upper surface of the encapsulation layer and the adhesive layer, so that the adhesive layer in the surrounding area adjacent to the through hole may not contact the inclined upper surface of the encapsulation layer.

Each of the at least one planarization layer and the second interlayer insulation layer disposed in the surrounding area may have a convex and concave structure, and the second interlayer insulation layer disposed in the surrounding area adjacent to the through hole comprises a planarization part, a surface of which is planar, and in the surrounding area, the at least one planarization layer may be disposed on the second interlayer insulation layer except for the planarization part.

The display device may further comprise a metallic convex and concave part disposed on the planarization part of the second interlayer insulation layer.

The metallic convex and concave part may comprise a first metallic layer, a second metallic layer on the first metallic layer, and a third metallic layer on the second metallic layer.

Each of the first metallic layer and the third metallic layer may have a greater width than the second metallic layer.

The second metallic layer may comprise a material of a greater etch rate than a material of each of the first metallic layer and the third metallic layer.

The display device may further comprise a dam disposed in the surrounding area in such a way that the dam surrounds the through hole.

According to one or more aspects of the present disclosure, a display device may comprise: a substrate; an active area comprising a plurality of sub pixels for displaying an image; a non-active area in the active area; an interlayer insulation layer disposed on the substrate; a planarization layer disposed on the interlayer insulation layer; and an encapsulation layer disposed on the planarization layer, wherein: the non-active area comprises a through hole and a surrounding area surrounding the through hole; a convex and concave structure is comprised in at least one or each of the following: the interlayer insulation layer disposed in the surrounding area and the planarization layer disposed in the surrounding area; and compared to an upper surface of the encapsulation layer disposed in the surrounding area away from the through hole, the upper surface of the encapsulation layer disposed in the surrounding area adjacent to the through hole is closer to the substrate.

Each of the interlayer insulation layer and the planarization layer disposed in the surrounding area may comprise the convex and concave structure, and the convex and concave structure of the interlayer insulation layer may overlap the convex and concave structure of the planarization layer.

The planarization layer disposed in the surrounding area may comprise openings that pass through the planarization layer in a thickness direction of the planarization layer, and the encapsulation layer disposed in the surrounding area may fill the openings of the planarization layer.

The interlayer insulation layer disposed in the surrounding area may comprise openings that pass through the interlayer insulation layer in a thickness direction of the interlayer insulation layer, and the encapsulation layer disposed in the surrounding area may fill the openings of the interlayer insulation layer.

The interlayer insulation layer disposed in the surrounding area may comprise openings that pass through the interlayer insulation layer in a thickness direction of the interlayer insulation layer, the planarization layer disposed in the surrounding area may comprise openings that pass through the planarization layer in a thickness direction of the planarization layer, and each of the openings of the interlayer insulation layer may overlap a respective one of the openings of the planarization layer.

The encapsulation layer may comprise a first encapsulation layer disposed on the planarization layer and a second encapsulation layer disposed on the first encapsulation layer, each of the planarization layer and the first encapsulation layer may comprise openings, and the openings of the planarization layer may overlap the openings of the first encapsulation layer.

According to one or more aspects of the present disclosure, a display device may comprise: a substrate; an active area comprising a plurality of sub pixels for displaying an image; a non-active area in the active area; a planarization layer disposed on the substrate; and an encapsulation layer disposed on the planarization layer, wherein: the non-active area may comprise a through hole and a surrounding area surrounding the through hole; the planarization layer disposed in the surrounding area may comprise a convex and concave structure; and compared to an upper surface of the encapsulation layer disposed in the surrounding area away from the through hole, the upper surface of the encapsulation layer disposed in the surrounding area adjacent to the through hole is closer to the substrate.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all equivalents thereof should be construed as falling within the scope of the present disclosure.

What is claimed is:

1. A display device, comprising:
a substrate;
an active area;
a non-active area in the active area;
a first interlayer insulation layer disposed on the substrate;
a second interlayer insulation layer disposed on the first interlayer insulation layer;
at least one planarization layer disposed on the second interlayer insulation layer; and
an encapsulation layer disposed on the at least one planarization layer,
wherein:
the non-active area comprises a through hole and a surrounding area surrounding the through hole;
at least a part of the second interlayer insulation layer and at least a part of the at least one planarization layer disposed in the surrounding area have a convex and concave structure;
at least a part of the encapsulation layer is disposed in the surrounding area adjacent to the through hole; and
a thickness of the at least a part of the encapsulation layer decreases toward the through hole.

2. The display device of claim 1, wherein:
the encapsulation layer comprises an inorganic encapsulation layer disposed on the at least one planarization layer and an organic encapsulation layer disposed on the inorganic encapsulation layer;
for the encapsulation layer, at least a part of the organic encapsulation layer is disposed in the surrounding area adjacent to the through hole; and
a thickness of the at least a part of the organic encapsulation layer decreases toward the through hole.

3. The display device of claim 2, wherein the at least a part of the organic encapsulation layer disposed in the surrounding area adjacent to the through hole is structured to incline toward the substrate.

4. The display device of claim 3, further comprising:
a first thin film transistor disposed on the substrate in the active area, and comprising a first active layer, a first gate electrode, a first source electrode and a first drain electrode;
a second thin film transistor disposed on the first thin film transistor, and comprising a second active layer, a second gate electrode, a second source electrode and second drain electrode; and
an organic light emitting diode disposed on the second thin film transistor,
wherein:
the first interlayer insulation layer is disposed between the first gate electrode and the second active layer in the active area; and
the second interlayer insulation layer is disposed among the second gate electrode, the second source electrode and the second drain electrode in the active area.

5. The display device of claim 4, further comprising:
an optical film disposed on the encapsulation layer; and
an adhesive layer disposed between the encapsulation layer and the optical film.

6. The display device of claim 5, wherein:
the adhesive layer is disposed to contact an upper surface of the encapsulation layer; and
the adhesive layer and the optical film disposed in the surrounding area adjacent to the through hole are structured to incline toward the substrate along an inclined upper surface of the organic encapsulation layer.

7. The display device of claim 5, wherein a gap is included between an inclined upper surface of the encapsulation layer and the adhesive layer, so that the adhesive layer in the surrounding area adjacent to the through hole does not contact the inclined upper surface of the encapsulation layer.

8. The display device of claim 5, wherein:
each of the at least one planarization layer and the second interlayer insulation layer disposed in the surrounding area has a convex and concave structure;
the second interlayer insulation layer disposed in the surrounding area adjacent to the through hole comprises a planarization part, a surface of which is planar; and
in the surrounding area, the at least one planarization layer is disposed on the second interlayer insulation layer except for the planarization part.

9. The display device of claim 8, further comprising a metallic convex and concave part disposed on the planarization part of the second interlayer insulation layer.

10. The display device of claim 9, wherein the metallic convex and concave part comprises a first metallic layer, a second metallic layer on the first metallic layer, and a third metallic layer on the second metallic layer.

11. The display device of claim 10, wherein each of the first metallic layer and the third metallic layer has a greater width than the second metallic layer.

12. The display device of claim 10, wherein the second metallic layer comprises a material of a greater etch rate than a material of each of the first metallic layer and the third metallic layer.

13. The display device of claim 1, further comprising a dam disposed in the surrounding area, wherein the dam surrounds the through hole.

14. A display device, comprising:
a substrate;
an active area comprising a plurality of sub pixels for displaying an image;
a non-active area in the active area;
an interlayer insulation layer disposed on the substrate;
a planarization layer disposed on the interlayer insulation layer; and
an encapsulation layer disposed on the planarization layer,
wherein:
the non-active area comprises a through hole and a surrounding area surrounding the through hole;
a convex and concave structure is comprised in at least one or each of the following: the interlayer insulation layer disposed in the surrounding area and the planarization layer disposed in the surrounding area; and
compared to an upper surface of the encapsulation layer disposed in the surrounding area away from the through hole, the upper surface of the encapsulation layer disposed in the surrounding area adjacent to the through hole is closer to the substrate.

15. The display device of claim 14, wherein:
each of the interlayer insulation layer and the planarization layer disposed in the surrounding area comprises the convex and concave structure; and
the convex and concave structure of the interlayer insulation layer overlaps the convex and concave structure of the planarization layer.

16. The display device of claim 14, wherein:
the planarization layer disposed in the surrounding area comprises openings that pass through the planarization layer in a thickness direction of the planarization layer; and
the encapsulation layer disposed in the surrounding area fills the openings of the planarization layer.

17. The display device of claim 16, wherein:
the interlayer insulation layer disposed in the surrounding area comprises openings that pass through the interlayer insulation layer in a thickness direction of the interlayer insulation layer; and
the encapsulation layer disposed in the surrounding area fills the openings of the interlayer insulation layer.

18. The display device of claim 14, wherein:
the interlayer insulation layer disposed in the surrounding area comprises openings that pass through the interlayer insulation layer in a thickness direction of the interlayer insulation layer;
the planarization layer disposed in the surrounding area comprises openings that pass through the planarization layer in a thickness direction of the planarization layer; and
each of the openings of the interlayer insulation layer overlaps a respective one of the openings of the planarization layer.

19. The display device of claim 14, wherein:
the encapsulation layer comprises a first encapsulation layer disposed on the planarization layer and a second encapsulation layer disposed on the first encapsulation layer;
each of the planarization layer and the first encapsulation layer comprises openings; and
the openings of the planarization layer overlap the openings of the first encapsulation layer.
